(19) United States
(12) Patent Application Publication
(10) Pub. No.: US 2025/0323216 A1
(43) Pub. Date: Oct. 16, 2025

(54) SEMICONDUCTOR STACK PACKAGE

(71) Applicant: Samsung Electronics Co., Ltd., Suwon-si (KR)

(72) Inventors: Seongyo KIM, Suwon-si (KR); Sang-Sick PARK, Suwon-si (KR); Hanmin LEE, Suwon-si (KR)

(73) Assignee: Samsung Electronics Co., Ltd., Suwon-si (KR)

(21) Appl. No.: 18/909,408

(22) Filed: Oct. 8, 2024

(30) Foreign Application Priority Data
Apr. 15, 2024 (KR) 10-2024-0050130

(51) Int. Cl. H01L 25/065; H01L 23/00; H01L 23/13; H01L 23/31; H01L 25/00

(52) U.S. Cl. CPC H01L 25/0655; H01L 23/13; H01L 23/3135; H01L 24/24; H01L 24/32; H01L 24/33; H01L 24/73; H01L 25/50; H01L 24/48; H01L 2224/24137; H01L 2224/244; H01L 2224/32137; H01L 2224/32155; H01L 2224/33181; H01L 2224/48145; H01L 2224/73265; H01L 2224/73267

(57) ABSTRACT

Example embodiments relate to a semiconductor stack package. The semiconductor stack package may include a semiconductor stack structure including a plurality of semiconductor packages having a fan-out wiring and a base substrate having an inclined surface supporting the plurality of semiconductor packages, and a rewiring structure on the semiconductor stack structure and having a rewiring pattern that is connected to the fan-out wiring, wherein the plurality of semiconductor packages are stacked on the inclined surface, and an inclined cut surface of each semiconductor package is flush with an upper surface of the semiconductor stack structure

### CROSS-REFERENCE TO RELATED APPLICATION

This application claims priority to Korean Patent Application No. 10-2024-0050130, filed in the Korean Intellectual Property Office on Apr. 15, 2024, the entire contents of which are hereby incorporated by reference.

### BACKGROUND

### Field

At least some example embodiments relate to a semiconductor stack package.

### Description of Related Art

A general stack package may have a structure in which a plurality of semiconductor chips are stacked in, for example, a vertical direction. The semiconductor chips may be electrically connected to each other by connecting connection pads on the plurality of chips using bonding wires. In such a case, vertical wire bonding technology may be applicable for the vertically stacked structure, but wire sweeping risk may increase as, for example, stacking steps are repeated.

Accordingly, a technology that can reduce performance defects in the stacked structure, and various methods for forming a semiconductor stack package with excellent or improved performance and/or improved degree of integration may be advantageous.

### SUMMARY

In order to address one or more problems (e.g., the problems described above and/or other problems not explicitly described herein), inventive concepts relate to a semiconductor stack package with improved electrical characteristics and reliability.

According to some example embodiments of inventive concepts, a semiconductor stack package may include a semiconductor stack structure including a plurality of semiconductor packages having a fan-out wiring and a base substrate having an inclined surface configured to support the plurality of semiconductor packages, and a rewiring structure on the semiconductor stack structure and having a rewiring pattern that is connected to the fan-out wiring, wherein the plurality of semiconductor packages are stacked on the inclined surface, and an inclined cut surface of each semiconductor package is flush with an upper surface of the semiconductor stack structure are flush with each other.

According to some example embodiments of inventive concepts, a semiconductor stack package may include a semiconductor stack structure including a plurality of semiconductor packages having a fan-out wiring and a base substrate having a first inclined surface configured to support the plurality of semiconductor packages and a second inclined surface connected to the first inclined surface, a rewiring structure on the semiconductor stack structure and having a rewiring pattern connected that is to the fan-out wiring, and a stack molding layer at least partially covering the plurality of semiconductor packages, wherein the plurality of semiconductor packages are stacked on the first inclined surface, an inclined cut surface of each semiconductor package is flush with an upper surface of the semiconductor stack structure, the plurality of semiconductor packages is in contact with only the first inclined surface with respect to the base substrate, and an inclination angle of the first inclined surface and an inclination of angle of the second inclined surface are different from each other.

According to some example embodiments of inventive concepts for, a method for manufacturing a semiconductor stack package may include providing a base substrate having an inclined surface, stacking, a plurality of semiconductor packages on the inclined surface, the plurality of semiconductor having a fan-out wiring, molding the plurality of semiconductor packages, grinding the plurality of semiconductor packages such that inclined cut surfaces of each of the semiconductor packages are coplanar with each other, and forming, on the inclined cut surface, a rewiring structure having a rewiring pattern that is connected to the fan-out wiring.

According to some example embodiments of inventive concepts, by cutting the fan-out semiconductor package obliquely on the base substrate including the inclined surface, a semiconductor stack package can be configured using the exposed surface of the rewiring pattern, thereby reducing or preventing defects caused by vertical wire bonding in the process of configuring the rewiring.

According to some example embodiments of inventive concepts, by including the semiconductor chips and/or semiconductor packages of various sizes, it is possible to provide a semiconductor stack package of various specifications without changing the process.

### BRIEF DESCRIPTION OF THE DRAWINGS

FIG. 1 is a plan view provided to explain the semiconductor stack package according to some example embodiments of inventive concepts.

FIG. 2 is a plan view provided to explain the semiconductor stack package according to some example embodiments of inventive concepts.

FIG. 3 is a cross-sectional view taken along line I-I of FIG. 1.

FIG. 4 is an enlarged view provided to explain a region of FIG. 2.

FIG. 5 is an enlarged view provided to explain a region of FIG. 3.

FIGS. 6 to 8 are diagrams provided to explain the semiconductor stack packages according to some example embodiments of inventive concepts.

FIGS. 9 and 10 are diagrams provided to explain semiconductor stack packages according to some example embodiments of inventive concepts.

FIG. 11 is a diagram provided to explain the semiconductor stack package according to some example embodiments of inventive concepts.

FIGS. 12 and 13 are diagrams provided to explain a method for manufacturing the base substrate according to some example embodiments of inventive concepts.

FIGS. 14 to 16 are diagrams schematically illustrating a method for manufacturing the semiconductor package according to some example embodiments of inventive concepts.

FIGS. 17 to 21 are diagrams illustrating a method for manufacturing the semiconductor stack package according to some example embodiments of inventive concepts.

### DETAILED DESCRIPTION

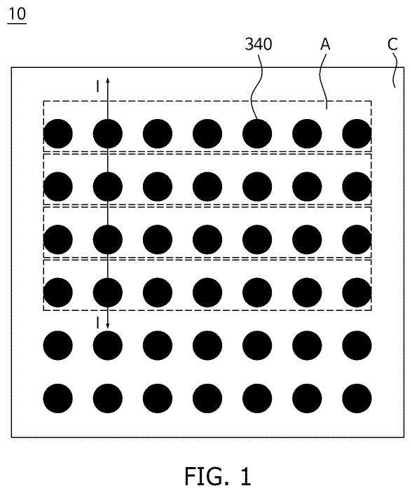

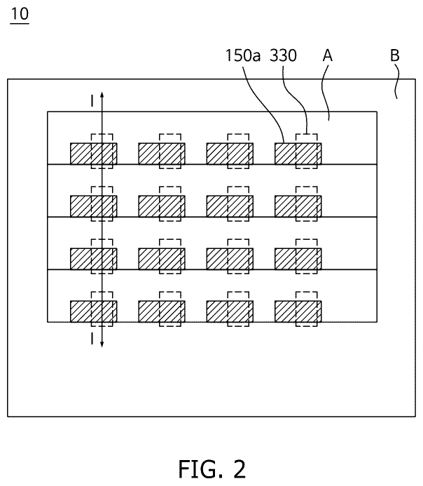

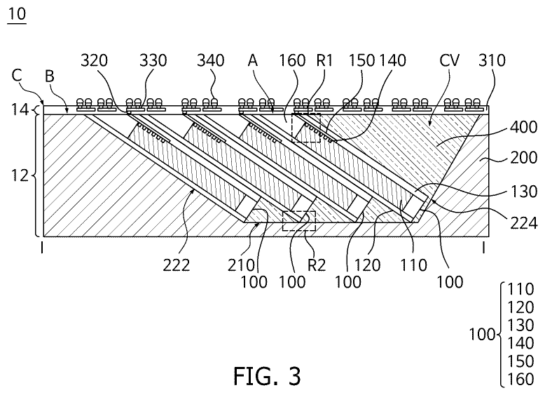

A semiconductor stack package 10 according to some example embodiments of inventive concepts will be described with reference to FIGS. 1 to 3. FIGS. 1 and 2 are plan views provided to explain the semiconductor stack package 10 according to some example embodiments of inventive concepts. FIG. 3 is a cross-sectional view taken along line I-I of FIG. 1.

FIGS. 1 and 2 are schematic diagrams provided to explain a plan view of the semiconductor stack package 10, and some of the components of FIG. 3 may be omitted from the illustrations in FIGS. 1 and 2.

Referring to FIGS. 1 to 3, the semiconductor stack package 10 according to some example embodiments may include a semiconductor stack structure 12 and a rewiring structure 14. The semiconductor stack package 10 may be a stacked semiconductor package configured by stacking a plurality of semiconductor packages 100 and electrically connecting the packages.

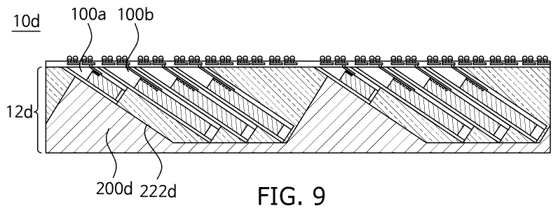

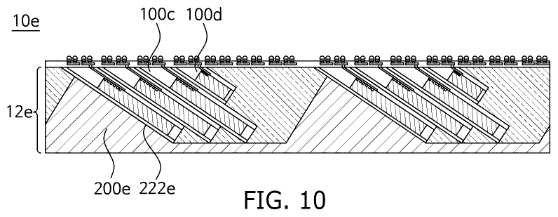

The semiconductor stack structure 12 may include semiconductor packages 100 and a base substrate 200. Each of the plurality of semiconductor packages 100 may, for example, have a same length, but example embodiments are not limited thereto. In another aspect, the plurality of semiconductor packages 100 may include semiconductor packages having at least one different length, for example at least one semiconductor package having a length that is different from others of the plurality of semiconductor packages 100. Details of some example embodiments will be described with reference to FIGS. 9 to 10.

A semiconductor package 100 may be, for example, a wafer level package (WLP). For example, any or each of the semiconductor packages 100 may be or include a fan-out wafer level package that forms or includes a rewiring pattern outside the chip using, for example, a molding wafer, but example embodiments are not limited thereto.

A semiconductor package 100 may include a chip 110, an adhesive layer 120, a chip insulating layer 130, a chip pad 140, a fan-out wiring 150, and a molding layer 160. The chip 110 may include, for example, one or more semiconductor devices. The adhesive layer 120 may be disposed on (for example, under) the chip 110 to stack (for example, in the stacking of) the semiconductor package 100. The chip insulating layer 130 may be disposed on (for example, on top of) the chip 110. The chip insulating layer 130 and/or the and the adhesive layer 120 may be formed of, for example, an epoxy resin, an acrylic resin, polyimide, and/or a combination of these, but are not limited thereto. The chip 110 may include the chip pad 140 for example, wiring connection(s). Individual fan-out wirings 150 considered together may be understood as a fan-out wiring 150 of the plurality of semiconductor chips 100. The fan-out wiring 150 may be disposed inside the chip insulating layer 130 and may be formed to extend to the outside of (for example, beyond) the chip 110 along a length direction of the chip 110. For example, the fan-out wiring 150 may be disposed in a fan-out area other than (for example, in addition to) a fan-in area in which the chip is positioned (for example, the fan out-wiring 150 may be understood as extending from a position overlapping with the chip 110 to a position not overlapping with the chip 110 in a direction perpendicular a length direction of the chip 110). The molding layer 160 may be formed adjacent to the chip 110. For example, the molding layers 160 may be disposed adjacent to both side surfaces of the chip 110. The molding layer 160 may include, for example, an epoxy molding compound (EMC), but is not limited thereto.

The base substrate 200 may be a structure that supports the semiconductor package 100. A cavity CV configured to accommodate at least the semiconductor packages 100 may be formed in (for example defined or at least partially defined by) the base substrate 200. The cavity may be understood as a cavity region and may be unfilled, filled, or partially filled. For example, the cavity CV may be defined or at least partially defined by a bottom surface 210, a first inclined surface 222 obliquely extending from one side of the bottom surface, and a second inclined surface 224 obliquely extending from another side of the bottom surface. In such a case, the semiconductor packages 100 may be understood as being disposed (for example, stacked) on (for example, in a way corresponding to) the first inclined surface 222, and the semiconductor packages 100 may be understood not to be disposed (for example, stacked) on (for example, in a way corresponding to) the second inclined surface 224. The base substrate 200 may include, for example, an epoxy molding compound (EMC), but is not limited thereto. A stack molding layer 400 covering or at least partially covering (for example, sealing) the plurality of semiconductor packages 100 may be formed on the base substrate 200. The stack molding layer 400 may include, for example, an EMC, but is not limited thereto.

According to some example embodiments, an upper surface B of the semiconductor stack structure 12 may include an inclined cut surface A of the semiconductor package 100. The inclined cut surface A may be a surface exposed by cutting the semiconductor packages 100 obliquely. The inclined cut surface A may be formed by, for example, polishing or cutting with a polishing device or a cutting device, or by etching through a chemical method, but example embodiments are not limited thereto. Referring to FIGS. 2 and 3, a cross-section 150a of the fan-out wiring of the semiconductor package 100 may be exposed (for example, at least partially exposed) on the inclined cut surface A. The exposed cross-section 150a of the fan-out wiring may be connected (for example, directly connected) to a rewiring pad 320. The exposed cross-section 150a of the fan-out wiring may be connected to a rewiring pattern 330 through (for example, by) the rewiring pad 320.

The upper surface B of the semiconductor stack structure 12 may form an acute angle with the first inclined surface 222 of the base substrate 200. For example, an angle formed between a virtual straight line extending from the first inclined surface 222 and the upper surface B of the semiconductor stack structure 12 may be greater than about 0° and less than about 90°. For example, the angle formed between the virtual straight line extending from the first inclined surface 222 and the upper surface B of the semiconductor stack structure 12 may be about 30 to 60 degrees. The angle formed between the virtual straight line extending from the first inclined surface 222 and the upper surface B of the semiconductor stack structure 12 may be adjusted according to, for example, the number of semiconductor packages, the size of semiconductor packages, the type of semiconductor packages, etc., but example embodiments are not limited thereto.

The rewiring structure 14 may include a rewiring insulating layer 310, the rewiring pad 320, the rewiring pattern 330, and the connection terminal 340. The rewiring pad 320 and the rewiring pattern 330 may be disposed in the rewiring insulating layer 310. The rewiring pad 320 may be connected to the fan-out wiring 150 on the inclined cut surface A. The rewiring pattern 330 may be connected to the rewiring pad 320 and may be formed inside the rewiring insulating layer 310. The connection terminal 340 may be disposed on an upper surface C of the rewiring insulating layer 310 and may be connected to the rewiring pattern 330. For example, the connection terminal 340 may be a solder ball, but example embodiments are not limited thereto.

The semiconductor stack package according to some example embodiments may reduce or prevent defects caused by the vertical wire bonding in the process of configuring the rewiring, by cutting the fan-out semiconductor package obliquely on the base substrate including the inclined surface and configuring the rewiring by using the exposed surface of the rewiring pattern.

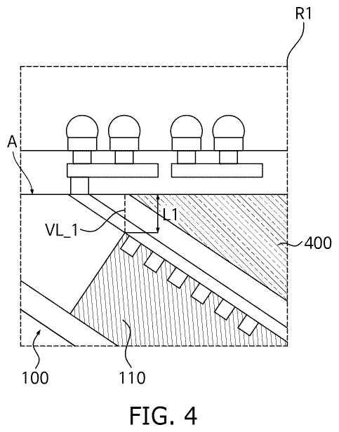

FIG. 4 is an enlarged view provided to explain a region R1 of FIG. 2.

According to some example embodiments, a distance between the chip 110 of the semiconductor package 100 and the inclined cut surface A may be maintained as a predetermined, or alternatively, desired distance or more. For example, a first distance L1 between a point on the uppermost end of the chip 110 of the semiconductor package 100 and a point at which a first imaginary line VL_1 extending in an upward direction perpendicular to the uppermost end of the chip 110 meets the inclined cut surface A may be maintained as a predetermined, or alternatively, desired distance or more. The predetermined, or alternatively, desired distance may refer to a distance that does not affect or substantially affect the performance of the chip 110 included in the semiconductor package 100. For example, the first distance L1 may be about 5 μm or more. Alternatively, the first distance L1 may be about 5 μm, but is not limited thereto. The height of the semiconductor stack package may be adjusted by adjusting the first distance L1 as needed or desired.

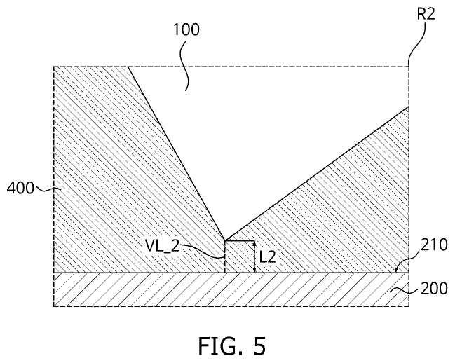

FIG. 5 is an enlarged view provided to explain a region R2 of FIG. 3.

According to some example embodiments, a distance between the semiconductor package 100 and the bottom surface 210 of the base substrate 200 may be maintained as a predetermined, or alternatively, desired distance or more. For example, a second distance L2 between a point on the lowermost end of the semiconductor package 100, and a point at which a second imaginary line VL_2 extending from the lowermost end of the semiconductor package 100 perpendicularly in a downward direction meets the bottom surface 210 of the base substrate 200 may be maintained as a predetermined, or alternatively, desired distance or more. The predetermined, or alternatively, desired distance may refer to a distance at which the semiconductor package 100 and the bottom surface 210 of the base substrate 200 do not contact (for example, directly contact or substantially directly contact) each other even due to, for example, vibration, impact, etc. For example, the second distance L2 may be about 5 μm or more, but example embodiments are not limited thereto. Alternatively, for example, the second distance L2 may be about 5 μm, but is not limited thereto. The height of the semiconductor stack package may be adjusted by adjusting the second distance L2 as needed or desired.

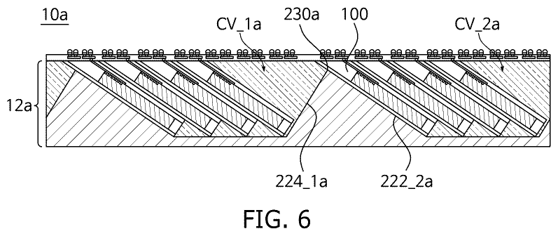

FIGS. 6 to 8 are diagrams provided to explain the semiconductor stack packages 10a, 10b, and 10c according to some example embodiments of inventive concepts.

According to some aspects, the semiconductor stack package may include (for example, define or at least partially define) a plurality of cavities. The plurality of cavities may include first cavities CV_1a, CV_1b, and CV_1c and second cavities CV_2a, CV_2b, and CV_2c adjacent to the first cavities CV_1a, CV_1b, and CV_1c. An inclination angle of each of second inclined surfaces 224_1a, 224_1b, and 224_1c of the first cavities CV_1a, CV_1b, and CV_1c and first inclined surfaces 222_2a, 222_2b, and 222_2c of the second cavities CV_2a, CV_2b, and CV_2c may be variously formed.

The first inclined surfaces 222_2a, 222_2b, and 222_2c of the second cavities CV_2a, CV_2b, and CV_2c may be surfaces on which the semiconductor package(s) 100 is disposed (for example, stacked), and the second inclined surfaces 224_1a, 224_1b, and 224_1c of the first cavities CV_1a, CV_1b, and CV_1c may be surfaces on which the semiconductor package 100 is not disposed. In an example, referring to FIG. 6, a point 230a at which the first inclined surface 222_2a of the second cavity CV_2a meets the second inclined surface 224_1a of the first cavity CV_1a may be formed in the semiconductor stack structure 12a.

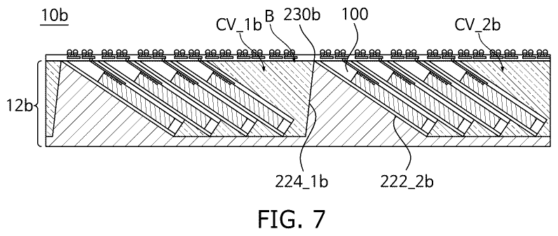

For example, referring to FIG. 7, a point 230b at which the first inclined surface 222_2b of the second cavity CV_2b meets the second inclined surface 224_1b of the first cavity CV_1b may be formed on the upper surface B of the semiconductor stack structure 12b.

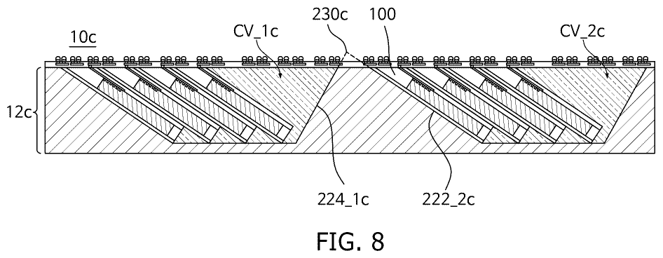

In yet another example, referring to FIG. 8, a point 230c (for example, a virtual point) at which a virtual line extending from the first inclined surface 222_2c of the second cavity CV_2c meets a virtual line the second inclined surface 224_1c of the first cavity CV_1c may be defined outside the semiconductor stack structure 12c.

It can be seen that the distance between the stacked semiconductor packages 100 decreases as the inclination angles of the second inclined surfaces 224_1a, 224_1b, and 224_1c of the first cavities CV_1a, CV_1b, and CV_1c increase. Accordingly, more semiconductor packages 100 can be arranged in a more limited space and production efficiency can be improved. For example, the inclination angles of the second inclined surfaces 224_1a, 224_1b, and 224_1c of the first cavities CV_1a, CV_1b, and CV_1c may be greater than the inclination angles of the first inclined surfaces 222_2a, 222_2b, and 222_2c of the second cavities CV_2a, CV_2b, and CV_2c. The inclination angles of the first inclined surfaces 222_2a, 222_2b, and 222_2c of the second cavities CV_2a, CV_2b, and CV_2c may be less than the inclination angles of the second inclined surfaces 224_1a, 224_1b, and 224_1c of the first cavities CV_1a, CV_1b, and CV_1c such that the semiconductor packages are stably or more stably stacked.

, For example, by designing the inclination angles of the second inclined surfaces 224_1a, 224_1b, and 224_1c of the first cavities CV_1a, CV_1b, and CV_1c to be relatively greater than the inclination angles of the first inclined surfaces 222_2a, 222_2b, and 222_2c of the second cavities CV_2a, CV_2b, and CV_2c, the productivity of the semiconductor stack package can be improved. For example, by forming the inclination angles of the second inclined surfaces 224_1a, 224_1b, and 224_1c of the first cavities CV_1a, CV_1b, and CV_1c equal to, or almost equal to a right angle, the production efficiency of the semiconductor stack package can be improved.

FIGS. 9 and 10 are diagrams provided to explain semiconductor stack packages 10d and 10e according to some example embodiments of inventive concepts.

According to some example embodiments, the semiconductor stack structures 12d and 12e of the semiconductor stack packages 10d and 10e may include semiconductor packages 100a, 100b, 100c, and 100d having various lengths. For example, referring to FIG. 9, the first semiconductor package 100a having a first length may be disposed on a first inclined surface 222d of the base substrate 200d, and the second semiconductor package 100b having a second length greater than the first length may be disposed on the first semiconductor package 100a. The first semiconductor package 100a having the first length may, for example, include a different type of semiconductor chip from that of the second semiconductor package 100b having the second length, but example embodiments are not limited thereto. For example, a semiconductor chip included in the first semiconductor package 100a may be or include a logic semiconductor chip and may be or include a microprocessor. For example, the semiconductor chip included in the first semiconductor package 100a may be or include, for example, a central processing unit (CPU), a controller, and/or an application specific integrated circuit (ASIC). A semiconductor chip included in the second semiconductor package 100b may, for example, be or include, a memory semiconductor chip. For example, the memory semiconductor chip may be a volatile memory semiconductor chip such as, for example, a dynamic random access memory (DRAM) or a static random access memory (SRAM), and/or may be a nonvolatile memory semiconductor chip such as a phase-change random access memory (PRAM), a magnetic random access memory (MRAM), a ferroelectric random access memory (FeRAM), and/or a resistive random access memory (RRAM). However, examples embodiments are not limited thereto.

As another example, referring to FIG. 10, the third semiconductor package 100c having a third length may be disposed on the first inclined surface 222e of a base substrate 200e, and the fourth semiconductor package 100d having a fourth length shorter than the third length may be disposed on the third semiconductor package 100c. Similar to the above, the semiconductor chip included in the third semiconductor package 100c may be, for example, a different type of chip from that of the semiconductor chip included in the fourth semiconductor package 100d, but example embodiments are not limited thereto.

FIGS. 9 and 10 illustrate an example where the semiconductor packages 100a and 100d having a relatively shorter length are arranged on the lowermost and uppermost sides of the stack, but example embodiments are not limited thereto. For example, a semiconductor package having a relatively shorter length may be disposed in the middle of the stack.

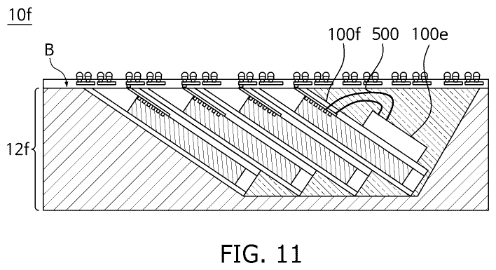

FIG. 11 is a diagram provided to explain the semiconductor stack package 10f according to some example embodiments of inventive concepts.

According to some example embodiments, the semiconductor stack package 10f may include at least one buried semiconductor chip 100e. The buried semiconductor chip 100e may represent a semiconductor chip or semiconductor package buried in the semiconductor stack structure 12f, in which the inclined cut surface is not exposed on the upper surface B of the semiconductor stack structure 12f. For example, as illustrated, the buried semiconductor chip 100e may be buried in the semiconductor stack structure 12f and connected to the adjacent semiconductor package 100f through a wire bonding 500. FIG. 11 illustrates that two lines of the wire bonding 500 are connected to the adjacent semiconductor package, but example embodiments are not limited thereto. For example, the number of wire bonding(s) is not limited to the above and there may be different numbers of wire bonding. In addition, the buried chip semiconductor chip 100e may be connected by wire bonding to another semiconductor package disposed in the same cavity of the base substrate.

For example, the buried semiconductor chip 100e may be or include a logic semiconductor chip and may be or include a microprocessor. For example, the buried semiconductor chip 100e may be or include a central processing unit (CPU), a controller, and/or an application specific integrated circuit (ASIC), but example embodiments are not limited thereto.

The semiconductor chip(s) included in the semiconductor package may be or include one or more memory semiconductor chip. For example, the memory semiconductor chip may be or include a volatile memory semiconductor chip such as a dynamic random access memory (DRAM) or a static random access memory (SRAM), or may be a nonvolatile memory semiconductor chip such as a phase-change random access memory (PRAM), a magnetic random access memory (MRAM), a ferroelectric random access memory (FeRAM), and/or a resistive random access memory (RRAM). However, example embodiments are not limited to the above.

As described above, the semiconductor stack package according to some example embodiments of inventive concepts may include the semiconductor chips and/or semiconductor packages of various sizes, thereby providing and/or allowing for semiconductor stack packages of various specifications without requiring or desiring changes or substantial changes in process.

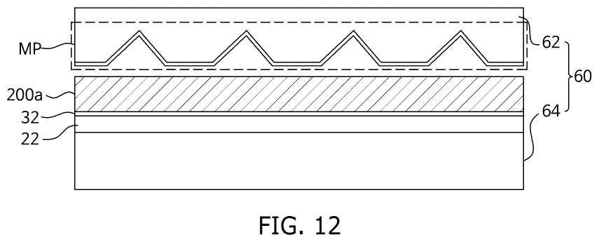

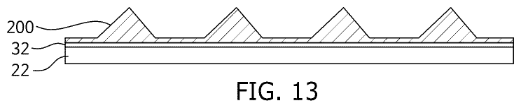

FIGS. 12 to 21 are diagrams showing intermediate stages, which are provided to explain methods for manufacturing a semiconductor package stack according to some example embodiments of inventive concepts. FIGS. 12 and 13 are diagrams provided to explain methods for manufacturing the base substrate 200 according to some example embodiments of inventive concepts.

The base substrate 200 may be formed using a mold 60. The mold 60 may include an upper mold 62 and a lower mold 64. A molding pattern MP may be formed in the upper mold 62. The molding pattern MP may correspond in shape to the package cavity or cavities (e.g., the cavity CV of FIG. 3) of the base substrate 200.

Referring to FIGS. 12 and 13, a mold resin in the form of a semi-finished product 200a (e.g., EMC in the form of a semi-finished product) may be attached to a base carrier substrate 22 using a base adhesive layer 32. The base adhesive layer 32 may include, for example, a tape attached by a tape lamination process, but is not limited thereto.

The base carrier substrate 22 with the mold resin 200a disposed thereon may be positioned on the lower mold 64. The upper mold 62 compresses the mold resin 200a downward to form the base substrate 200 including a cavity to accommodate at least one or more semiconductor packages.

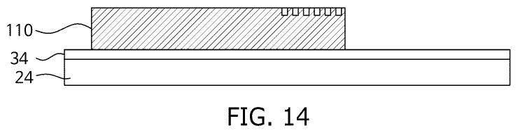

FIGS. 14 to 16 are diagrams schematically illustrating a methods for manufacturing the semiconductor package(s) 100 according to some example embodiments of inventive concepts.

A semiconductor package 100 may include a fan-out wafer level package that forms or includes a rewiring pattern outside the chip using a molding wafer. FIGS. 14 to 16 illustrate a method for manufacturing one semiconductor package 100 for convenience of explanation, but example embodiments are not limited thereto. The semiconductor package 100 may be manufactured using a plurality of chips.

First, referring to FIG. 14, the chip 110 may be attached onto a package carrier substrate 24 using a chip adhesive layer 34. The chip adhesive layer 34 may be or include, for example, a tape attached by a tape lamination process, but is not limited thereto.

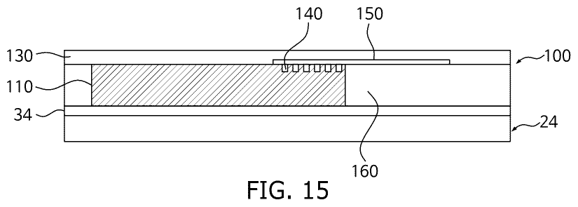

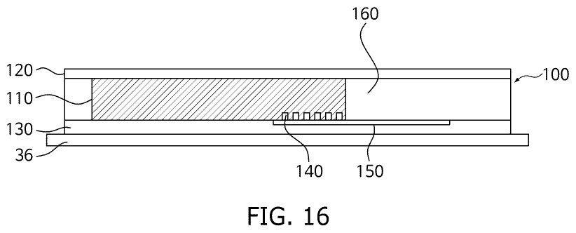

Referring to FIGS. 15 and 16, the molding layer 160 may be formed adjacent to the chip 110, and the fan-out wiring 150 may be formed inside the chip insulating layer 130 disposed on the chip 110 and the molding layer 160. The fan-out wiring 150 may be, for example, a rewiring layer (RDL) and may be formed to extend outwardly of the chip 110. Although only one chip 110 is illustrated in FIG. 15, this is for convenience of explanation, and a plurality of chips may be disposed on the package carrier substrate 24. In such a case, the molding layer 160 may be formed between a plurality of chips, and a rewiring layer between a plurality of chips may be formed inside the chip insulating layer 130 that is disposed on the molding layer 160. A singulation process may be, for example, performed. For example, a stack package adhesive layer 36 may be adhered on the plurality of semiconductor packages 100 arranged on the package carrier substrate 24, which can then be flipped over and disposed on the substrate, but example embodiments are not limited thereto. The semiconductor package 100 may be individually cut in units of packages. Accordingly, the semiconductor package 100 having the fan-out wiring 150 can be obtained.

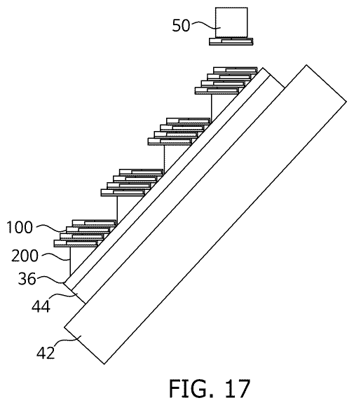

FIGS. 17 to 21 are diagrams illustrating methods for manufacturing the semiconductor stack package 10 according to some example embodiments of inventive concepts.

Methods for manufacturing the semiconductor stack package 10 may be performed by an apparatus for manufacturing a semiconductor (e.g., an apparatus for manufacturing a semiconductor stack package). The apparatus for manufacturing the semiconductor (e.g., a substrate control device) may provide a base substrate having an inclined surface. For example, the apparatus for manufacturing the semiconductor may rotate a carrier supporting the base substrate to adjust the inclined surface of the base substrate to a horizontal or substantially horizontal plane. By rotating the carrier supporting the base substrate by the inclination angle of the inclined surface of the base substrate, the inclined surface of the base substrate may be adjusted to the horizontal surface. For example, if the inclined surface of the base substrate has the inclination of or about 45 degrees, the carrier supporting the base substrate may be rotated by or about 45 degrees, and accordingly, the inclined surface of the base substrate may correspond to the horizontal surface.

The apparatus for manufacturing the semiconductor (e.g., a transfer device) may stack a plurality of semiconductor packages having fan-out wiring on the inclined surface. The fan-out wiring may be provided in the form of a plurality of fan-out wirings, for example, each of the plurality of semiconductor wirings may include a fan-out wiring of the plurality of fan-out wirings. For example, the apparatus for manufacturing the semiconductor may stack the semiconductor packages such that a plurality of semiconductor packages are in contact with only the inclined surface of the base substrate. Only the lower surface among the surfaces of a semiconductor package of the stacked semiconductor packages that is disposed on the lowermost side of the semiconductor stacked structure, may be in contact (for example, direct contact) with the inclined surface of the base substrate. The other semiconductor packages except for the semiconductor package disposed on the lowermost side of the stacked semiconductor packages do not contact (for example, directly contact) the base substrate.

Each of the plurality of semiconductor packages may include an adhesive layer. In such a case, the apparatus for manufacturing the semiconductor may connect (for example, adhere) the semiconductor packages to the base substrate by using the adhesive layer, which may be provided as a plurality of adhesive layers. For example, one of the plurality of semiconductor packages may be adhered to the base substrate by the adhesive layer. In addition, the apparatus for manufacturing the semiconductor may adhere the semiconductor packages to each other using the adhesive layers. For example, two adjacent semiconductor packages of the plurality of semiconductor packages may be adhered to each other by an adhesive layer. Each of the plurality of semiconductor packages may include, for example, one or more semiconductor packages having the same or substantially the same length. The plurality of semiconductor packages may include at least one semiconductor package having a different length. For example, at least one of the plurality of semiconductor packages may have a length that is different from a length of other ones of the plurality of semiconductor packages.

The apparatus for manufacturing the semiconductor (e.g., a mold control device) may mold a plurality of semiconductor packages.

The apparatus for manufacturing the semiconductor (e.g., a polishing device or a cutting device) may grind a plurality of semiconductor packages such that the inclined cut surfaces of each of the semiconductor packages form the same plane (for example, are coplanar or substantially coplanar with each other). The fan-out wiring of the semiconductor package may be exposed (for example, at least partially exposed) on the inclined cut surface of each semiconductor package.

The apparatus for manufacturing the semiconductor (e.g., a rewiring layer forming device) may form, on the inclined cut surface, a rewiring structure having rewiring connected to the fan-out wiring. In such a case, a connection terminal connected to the rewiring pattern may be formed on the rewiring structure.

Referring to FIG. 17, the semiconductor package 100 may be stacked on the base substrate 200 having the inclined surface. For example, a stack package carrier 44 may be disposed on a stage 42 with adjustable angle. The base substrate 200 may be attached to the stack package carrier 44 through the stack package adhesive layer 36. The base substrate 200 may include an inclined surface (e.g., the first inclined surface 222 of FIG. 3) on which a semiconductor package 100 is disposed. The stage 42 may be rotated such that the inclined surface with the semiconductor package 100 disposed thereon is horizontal or substantially horizontal to the ground. The semiconductor package 100 may be transferred by, for example, a transfer device 50 and stacked on the inclined surface of the base substrate 200. In such a case, the semiconductor package 100 may be disposed so as not to contact (for exactly, not directly contact) the bottom surface of the base substrate 200.

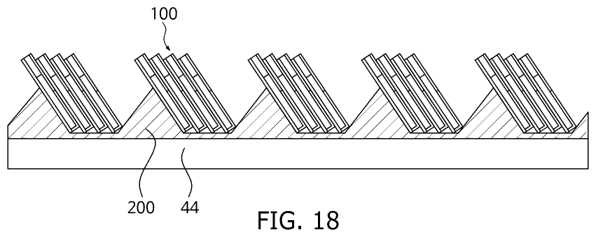

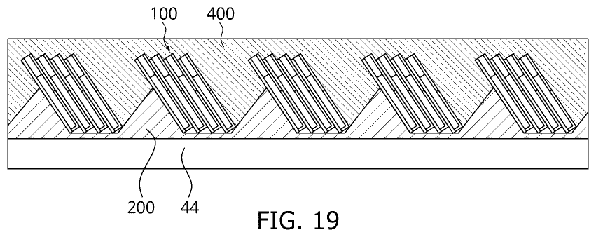

Referring to FIGS. 18 and 19, the stack package carrier 44 supporting the base substrate 200 on which the semiconductor package 100 is disposed may be positioned such that the upper surface thereof is horizonal, substantially horizontal, or approximately horizontal to the ground. The stack molding layer 400 may be formed on the base substrate 200 such that the semiconductor package 100 is covered or at least partially covered (for example, sealed). In such case, a height of the upper surface of the stack molding layer 400 may be greater than a height of the uppermost end of the semiconductor package 100 disposed on the base substrate 200. For example, the uppermost end of the semiconductor package 100 disposed on the base substrate 200 may be positioned below the upper surface of the stack molding layer 400.

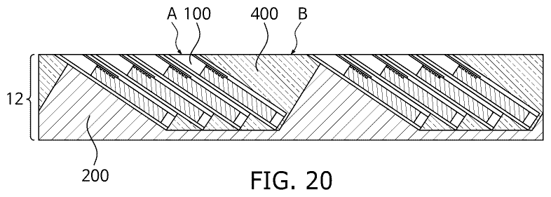

Referring to FIG. 20, the semiconductor stack structure 12 may be formed by partially cutting upper ends of the stack molding layer 400 and the semiconductor package 100. For example, part of the upper ends of the stack molding layer 400 and the semiconductor package 100 may be cut by, for example, a polishing device and/or a cutting device, or may be, for example, etched through, for example, a chemical method, but example embodiments are not limited thereto. The upper surface B of the semiconductor stack structure 12 may include the inclined cut surface A of the semiconductor package 100. The cross-section 150a of the fan-out wiring of the semiconductor package 100 may be exposed on the inclined cut surface A.

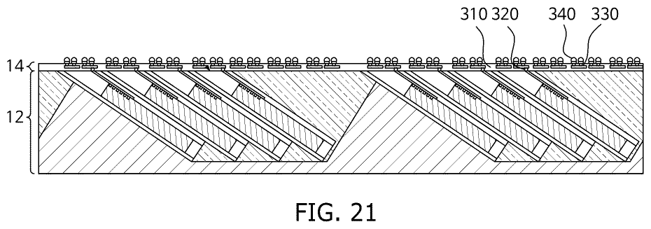

Referring to FIG. 21, the rewiring structure 14 may be formed on the upper surface of the semiconductor stack structure 12. The rewiring structure 14 may include the rewiring insulating layer 310, the rewiring pad 320, the rewiring pattern 330, and the connection terminal 340. For example, the rewiring insulating layer 310 may be formed on the upper surface of the semiconductor stack structure 12. The rewiring pad 320 and the rewiring pattern 330 may be arranged in the rewiring insulating layer 310. The rewiring pad 320 may be connected to the fan-out wiring 150 on the inclined cut surface A. The rewiring pattern 330 may be connected to the rewiring pad 320 and may be formed inside the rewiring insulating layer 310. The connection terminal 340 may be disposed on the upper surface C of the rewiring insulating layer 310 and may be connected to the rewiring pattern 330. For example, the connection terminal 340 may be a solder ball, but example embodiments are not limited thereto.

Accordingly, the semiconductor stack package as described above in FIGS. 1 to 11 may be provided.

Although some example has been described above by way of certain aspects and drawings, the example embodiments are not limited thereto, and it goes without saying that various changes and modifications can be made by those of ordinary skill in the art within the spirit and scope of inventive concepts and the claims to be described below.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

1. A semiconductor stack package, comprising:
a semiconductor stack structure including
a plurality of semiconductor packages including a fan-out wiring, and
a base substrate having an inclined surface configured to support the plurality of semiconductor packages; and
a rewiring structure on the semiconductor stack structure and having a rewiring pattern that is connected to the fan-out wiring,
wherein the plurality of semiconductor packages are stacked on the inclined surface, and
an inclined cut surface of each semiconductor package is flush with an upper surface of the semiconductor stack structure.

2. The semiconductor stack package according to claim 1, wherein each inclined cut surface corresponds to a surface through which the fan-out wiring is exposed.

3. The semiconductor stack package according to claim 1, wherein the fan-out wiring is connected to the rewiring pattern on the upper surface of the semiconductor stack structure.

4. The semiconductor stack package according to claim 3, wherein the rewiring structure includes a connection terminal connected to the rewiring pattern.

5. The semiconductor stack package according to claim 1, wherein the upper surface of the semiconductor stack structure forms an acute angle with the inclined surface.

6. The semiconductor stack package according to claim 1, wherein the plurality of semiconductor packages is in contact with only the inclined surface with respect to the base substrate.

7. The semiconductor stack package according to claim 6, wherein each of the plurality of semiconductor packages includes an adhesive layer, and
one of the plurality of semiconductor packages is adhered to the base substrate by the adhesive layer thereof.

8. The semiconductor stack package according to claim 7, wherein two adjacent semiconductor packages of the plurality of semiconductor packages are adhered to each other by one of the adhesive layers.

9. The semiconductor stack package according to claim 1, wherein each of the plurality of semiconductor packages has a same length.

10. The semiconductor stack package according to claim 1, wherein at least one of the plurality of semiconductor packages has a different length.

11. The semiconductor stack package according to claim 1, further comprising a buried semiconductor chip in the semiconductor stack structure,
wherein the buried semiconductor chip is connected to at least one of the plurality of semiconductor packages by wire bonding.

12. A semiconductor stack package, comprising:
a semiconductor stack structure including
a plurality of semiconductor packages including a fan-out wiring, and
a base substrate having a first inclined surface, the first inclined surface configured to support the plurality of semiconductor packages, connected to a second inclined surface;
a rewiring structure on the semiconductor stack structure and including a rewiring pattern that is connected to the fan-out wiring; and
a stack molding layer at least partially covering the plurality of semiconductor packages,
wherein the plurality of semiconductor packages are stacked on the first inclined surface,
an inclined cut surface of each semiconductor package is flush with an upper surface of the semiconductor stack structure are,
the plurality of semiconductor packages is in contact with only the first inclined surface with respect to the base substrate, and
an inclination angle of first inclined surface and an inclination angle of the second inclined surface are different from each other.

13. A method for manufacturing a semiconductor stack package, comprising:
providing a base substrate having an inclined surface;
stacking, a plurality of semiconductor packages on the inclined surfaced, the plurality of semiconductor packages including a fan-out wiring;
molding the plurality of semiconductor packages;
grinding the plurality of semiconductor packages such that inclined cut surfaces of each of the semiconductor packages are coplanar with each other; and
forming, on the inclined cut surface, a rewiring structure having a rewiring pattern, the rewiring pattern connected to the fan-out wiring.

14. The method according to claim 13, wherein the providing the base substrate includes rotating a carrier that supports the base substrate to adjust the inclined surface to a horizontal plane.

15. The method according to claim 13, wherein the stacking the plurality of semiconductor packages includes stacking the plurality of semiconductor packages such that the plurality of semiconductor packages is in contact with only the inclined surface with respect to the base substrate.

16. The method according to claim 15, wherein each of the plurality of semiconductor packages includes an adhesive layer, and
the stacking the plurality of semiconductor packages includes adhering one of the plurality of semiconductor packages to the base substrate by the adhesive layer thereof.

17. The method according to claim 16, wherein the stacking the plurality of semiconductor packages includes adhering two adjacent semiconductor packages of the plurality of semiconductor packages to each other by one of the adhesive layers.

18. The method according to claim 13, further comprising:
Forming a connection terminal on the rewiring structure, the connection terminal connected to the rewiring pattern.

19. The method according to claim 13, wherein each of the plurality of semiconductor packages has a same length.

20. The method according to claim 13, wherein at least one of the plurality of semiconductor packages has a different length.
